(19) United States
(12) Patent Application Publication
(10) Pub. No.: US 2010/0177000 A1
(43) Pub. Date: Jul. 15, 2010

(54) AUTOMATIC ANTENNA OPTIMIZATION SYSTEM

(75) Inventors: ARTHUR BRISEBOIS, CUMMING, GA (US); MELVIN FRERKING, NORCROSS, GA (US)

Correspondence Address: AT&T Legal Department - T&W;Attn: Patent Docketing, Room 2A-207, One AT&T Way, Bedminster, NJ, 07921, US

(73) Assignee: AT&T MOBILITY II LLC, Atlanta, GA (US)

(21) Appl. No.: 12/354,157

(22) Filed: Jan. 15, 2009

(51) Int. Cl. H01Q 3/00; G01R 29/08

(52) U.S. Cl. 343/703; 343/763

(57) ABSTRACT

The claimed subject matter provides a system and/or a method that facilitates receiving a terrestrial broadcast service from a transmitter. An antenna steering component can automatically maneuver a directional antenna with a 360 degree azimuth sweep in order to collect information related to a signal quality for a channel and a corresponding transmitter. An antenna system controller can ascertain an antenna azimuth for the directional antenna for each channel based upon the collected information, wherein the antenna azimuth corresponds to a position of the directional antenna that receives a level of reception from the transmitter.

### TECHNICAL FIELD

The subject innovation relates to terrestrial broadcast reception and, more particularly, to automatic antenna optimization for over the air reception.

### BACKGROUND

Terrestrial broadcast transmission receivers (e.g., radio, television, etc.) can benefit from improved performance provided by the use of directional receive antennas. Such directional antennas can receive greater signal in a portion of a 360 degree arc (e.g., main lobe) whilst suppressing interference from other portions of the arc (e.g., side and back lobes). When aimed properly (e.g., main lobe pointed towards desired transmitter antennae), directional antennas can improve the signal to noise ratio (e.g., quality) of a desired signal. This effect can result in greater range and quality for content delivered over a selected transmitter/receiver pair. Terrestrial broadcast transmission receivers must selectively process signals coming from a number of transmitters and locations: typically one at a time. In this case, the quality of the chosen signal (e.g., channel) can be dependent upon the optimal aiming of the antenna main lobe towards the desired transmitter. The terrestrial transmitters can surround the receiver which can form a constellation of up to 360 degrees.

Directional antennas must therefore be re-aimed each time the user selects a different channel broadcast coming from a different transmitter location. In the past, various motorized antenna rotor products allowed a user to remotely aim the antenna for optimal reception of the desired channel yet required manual trial and error to fine-tune antenna aiming. HDTV and HD radio further exacerbate the problem. For instance, there are lots more channels to tune, as HDTV and HD radio add sub-channels offering lots more content and potential for surfing. Moreover, HDTV is more susceptible to multipath effects and signal degradation compared to analog TV. Furthermore, HDTVs (for example) are much larger with higher resolution that can expose minor imperfections otherwise overlooked with analog television reception. Optimizing a single antenna for multiple received channels increases the complexity of manual tuning by an order of magnitude. Additionally, consumer electronics are becoming much more integrated in order to ease use and improve popularity. For instance, tuning a television and antenna whilst channel surfing can be challenging and too involved for the average consumer.

### SUMMARY

The following presents a simplified summary of the innovation in order to provide a basic understanding of some aspects described herein. This summary is not an extensive overview of the claimed subject matter. It is intended to neither identify key or critical elements of the claimed subject matter nor delineate the scope of the subject innovation. Its sole purpose is to present some concepts of the claimed subject matter in a simplified form as a prelude to the more detailed description that is presented later.

The subject innovation relates to systems and/or methods that facilitate automatically optimizing a directional antenna in order to provide optimized over the air reception. An antenna system controller can leverage an antenna steering component to maneuver a directional antenna with a 360 degree azimuth sweep in order to collect signal strength related to a transmitter. The antenna system controller can enable a user device equipment to receive reception for a channel that corresponds to a transmitter, wherein the antenna system controller leverages the collected signal strength data to position the directional antenna. In other words, the antenna system controller can provide an optimized directional antenna position in light of a survey or scan of positions and signal strengths for various transmitters.

In another aspect of the subject innovation, a first directional antenna can be dedicated to a scanning mode in which signal strength for various transmitters can be continuously monitored and/or tracked. A second directional antenna can be utilized in a reception mode in which channel requests are handled by positioning the second directional antenna in accordance with the first directional antenna monitoring. Moreover, the antenna system controller can manage a plurality of channel requests from a plurality of user device equipment, wherein analysis can identify an optimal position for the directional antenna. In other aspects of the claimed subject matter, methods are provided that facilitate collecting transmitter information in order to automatically identify optimal antenna aiming for improved signal quality with user device equipment.

The following description and the annexed drawings set forth in detail certain illustrative aspects of the claimed subject matter. These aspects are indicative, however, of but a few of the various ways in which the principles of the innovation may be employed and the claimed subject matter is intended to include all such aspects and their equivalents. Other advantages and novel features of the claimed subject matter will become apparent from the following detailed description of the innovation when considered in conjunction with the drawings.

### BRIEF DESCRIPTION OF THE DRAWINGS

FIG. 1 illustrates a block diagram of an exemplary system that facilitates automatically optimizing a directional antenna in order to provide optimized over the air reception.

FIG. 2 illustrates a block diagram of an exemplary system that facilitates collecting transmitter information in order to automatically identify optimal antenna aiming for improved signal quality with user device equipment.

FIG. 3 illustrates a block diagram of an exemplary system that facilitates evaluating antenna aiming for multiple channel requests in which an efficient directional antenna aiming can be employed to suite each channel request.

FIG. 4 illustrates a block diagram of an exemplary system that facilitates utilizing two or more directional antennas for automatic configuration to receive terrestrial broadcast services.

FIG. 5 illustrates a block diagram of exemplary system that facilitates identifying direction antenna positions that correspond to an optimal signal from a transmitter.

FIG. 6 illustrates a block diagram of an exemplary system that facilitates automatically inferring optimal antenna positions for efficient receipt of terrestrial broadcast services.

FIG. 7 illustrates an exemplary methodology for automatically optimizing a directional antenna in order to provide optimized over the air reception.

FIG. 8 illustrates an exemplary methodology that facilitates evaluating antenna aiming for multiple channel requests in which an efficient directional antenna aiming can be employed to suit each channel request.

FIG. 9 is a block diagram of a computing system in which various aspects described herein can function.

### DETAILED DESCRIPTION

The claimed subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the claimed subject matter may be practiced without these specific details. In other instances, well-known structures and devices are shown in block diagram form in order to facilitate describing the subject innovation.

As utilized herein, terms “component,” “system,” “data store,” “evaluator,” “controller,” “transmitter,” “antenna,” “equipment,” and the like are intended to refer to a computer-related entity, either hardware, software (e.g., in execution), and/or firmware. For example, a component can be a process running on a processor, a processor, an object, an executable, a program, a function, a library, a subroutine, and/or a computer or a combination of software and hardware. By way of illustration, both an application running on a server and the server can be a component. One or more components can reside within a process and a component can be localized on one computer and/or distributed between two or more computers.

Furthermore, the claimed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ). Additionally it should be appreciated that a carrier wave can be employed to carry computer-readable electronic data such as those used in transmitting and receiving electronic mail or in accessing a network such as the Internet or a local area network (LAN). Of course, those skilled in the art will recognize many modifications may be made to this configuration without departing from the scope or spirit of the claimed subject matter. Moreover, the word “exemplary” is used herein to mean serving as an example, instance, or illustration. Any aspect or design described herein as “exemplary” is not necessarily to be construed as preferred or advantageous over other aspects or designs.

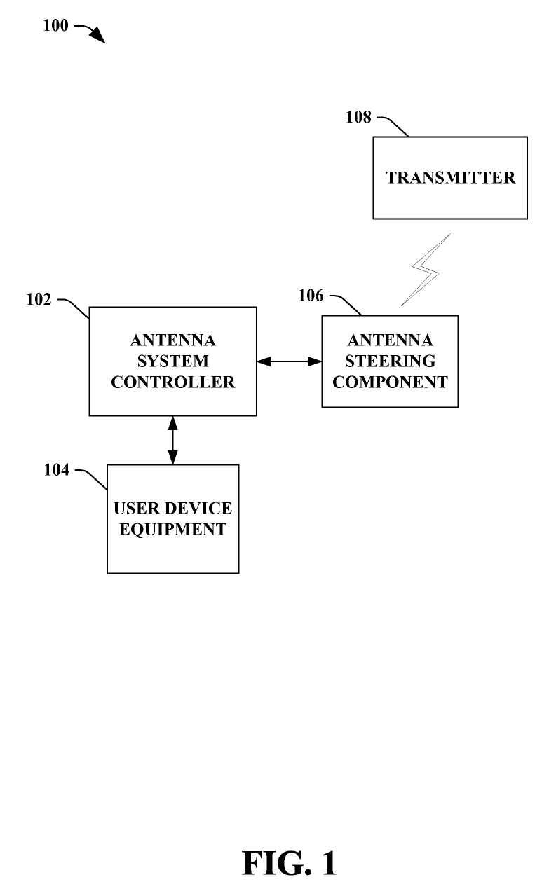

Now turning to the figures, FIG. 1 illustrates a system 100 that facilitates automatically optimizing a directional antenna in order to provide optimized over the air reception. The system 100 can include an antenna system controller 102 that can automatically survey and collect information related to antenna positions in order to receive a transmission from a transmitter 108, wherein the transmission can be utilized by a user device equipment 104. The antenna system controller 102 can collect information related to channels and/or the transmitter 108 based upon signal quality detected from a directional antenna (not shown). The directional antenna can be identify signal quality from the transmitter 108 based upon a 360 azimuth sweep. In general, the antenna system controller 102 can ascertain information related to a position for a directional antenna in order to provide a level of reception for a channel and/or transmitter, wherein such information can be utilized to optimize reception for the user device equipment 104.

For example, the antenna system controller 102 can provide a signal survey in order to identify antenna positions (e.g., angle, azimuth angle, direction, etc.) for each channel and/or transmitter 108. The antenna system controller 102 can communicate a command that can automatically maneuver a directional antenna utilizing the antenna steering component 106. Upon collection of the antenna position(s), the antenna system controller 102 can manage requests from the user device equipment 104. For example, the user device equipment 104 can request a signal reception from channel A, wherein the antenna system controller 102 can ensure the directional antenna is positioned (e.g., utilizing the antenna steering component 106) such that a level of reception is provided for optimal signal reception.

The system 100 can provide automatic directional antenna positioning in order to provide an optimal level of reception for at least one channel from the transmitter 108. By enabling an automated system 100 to survey and manage directional antenna positions, user device equipment 104 can receive a level of reception for each channel at a defined directional antenna position. For example, the level of reception can be based upon a pre-defined level of signal quality (e.g., a measurement of signal quality, a % of a signal quality, a % of a maximum signal quality, etc.), a maximum detected signal quality from the transmitter 108, a defined level of signal quality, and/or any other suitable defined level of signal quality that can be utilized by the user device equipment 104.

It is to be appreciated that the user device equipment 104 can relate to any suitable equipment that can receive data related to over the air broadcasts such as, but not limited to, high definition (HD) television signals, satellite signals, analog signals, digital signals, wireless signals, network signals, server communications, etc. It is to be appreciated that the directional antenna can identify a tuned channel via detection of a local oscillator frequency from outside a receiver enclosure. Moreover, the directional antenna can forward or communicate the tuned channel information to the antenna system controller 102 via a wired or wireless mechanism.

In addition, the system 100 can include any suitable and/or necessary interface component (not shown), which provides various adapters, connectors, channels, communication paths, etc. to integrate the antenna system controller 102 into virtually any operating and/or database system(s) and/or with one another. In addition, the interface component can provide various adapters, connectors, channels, communication paths, etc., that provide for interaction with the antenna system controller 102, the user device equipment 104, the antenna steering component 106, the transmitter 108, and any other device and/or component associated with the system 100.

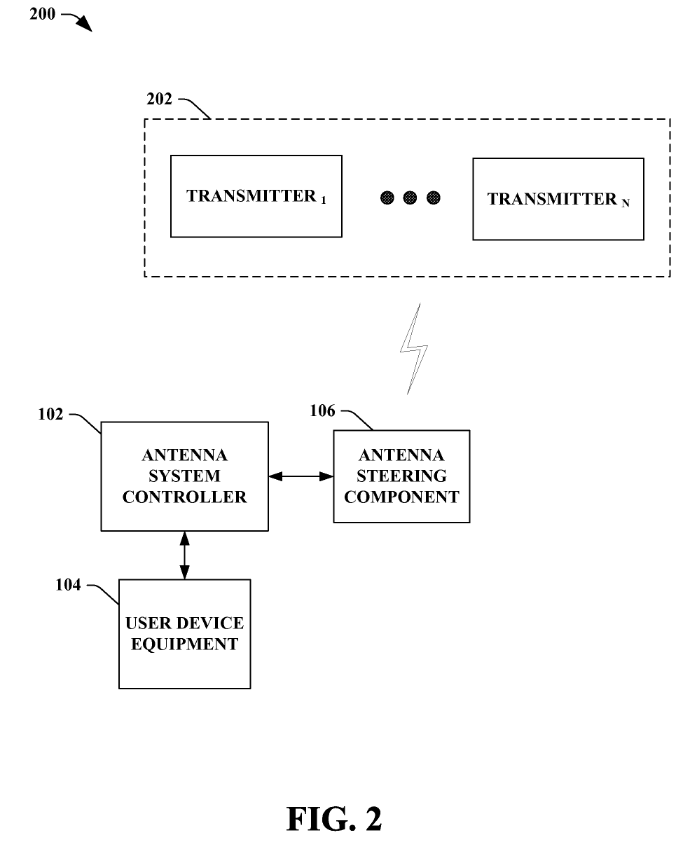

FIG. 2 illustrates a system 200 that facilitates collecting transmitter information in order to automatically identify optimal antenna aiming for improved signal quality with user device equipment. The system 200 can include the antenna system controller 102 that can collect signal reception data by implementing a portion of a 360 azimuth sweep for a directional antenna via the antenna steering component 106. Particularly, the antenna steering component 106 can maneuver a directional antenna in order to identify positions to which the directional antenna can receive a level of reception for a channel that corresponds to a specific transmitter.

In accordance with an aspect of the claimed subject matter, the antenna system controller 102 can collect signal information (e.g., directional antenna position, etc.) from a plurality of transmitters 202. Thus, it is to be appreciated that there can be any suitable number of transmitters 202, such as transmitter ₁ to transmitter _{N}, where N is a positive integer. For example, a first transmitter can correspond to a first channel, whereas a second transmitter can correspond to a second channel. The user device equipment 104 can be utilized to tune to various channels that correspond to the respective transmitter.

The antenna system controller 102 can utilize the antenna steering component 106 to survey (e.g., scan, record, etc.) the transmitters 202 in order to ascertain each transmitter and directional antenna position (e.g., azimuth angle, direction, etc.). Thus, the antenna system controller 102 can track or monitor directional antenna positions that correlate to the transmitters 202 in order to allow the user device equipment 104 to receive a level of reception therefrom. It is to be appreciated that the antenna system controller 102 can continuously and automatically gather information related to directional antenna position for transmitters 202 in order to provide user device equipment 104 with a level of reception for each channel/transmitter relationship. In other words, the user device equipment 104 can be periodically or continuously updated with up-to-date directional antenna position for each channel/transmitter relationship, wherein the periodic or continuous update is based upon a frequency of directional antenna scanning and recording of signal quality for transmitters 202. It is to be appreciated that scanning can be an initial scan, a periodic scan, a re-occurring scan, a user-implemented scan, a transmitter-implemented scan, a frequency defined by the antenna system controller 102, and the like.

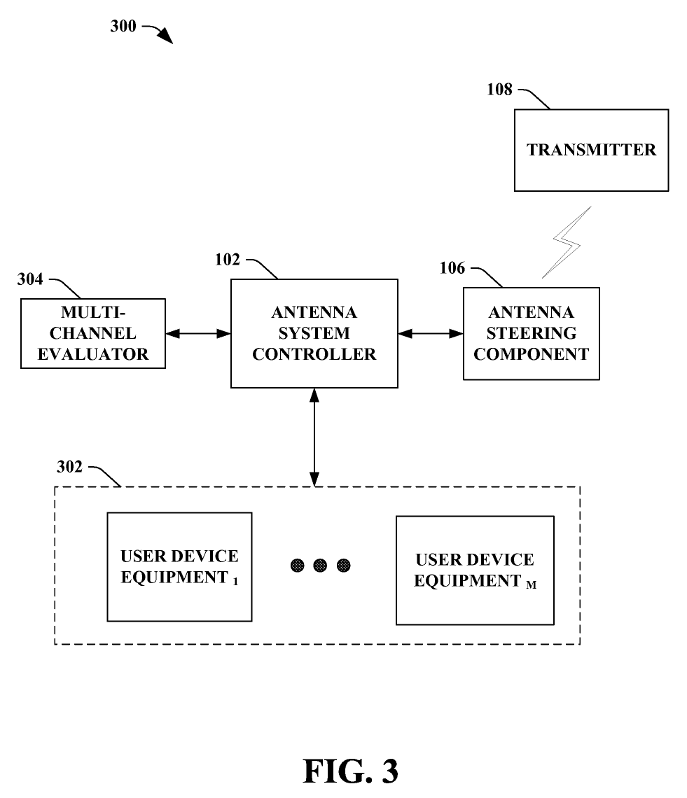

FIG. 3 illustrates a system 300 that facilitates evaluating antenna aiming for multiple channel requests in which an efficient directional antenna aiming can be employed to suite each channel request. The antenna system controller 102 can enable the antenna steering component 106 to automatically maneuver a directional antenna to a position in order to receive an optimized level of reception from the transmitter 108. In accordance with an aspect of the subject innovation, the antenna system controller 102 can manage multiple channel requests from a plurality of user device equipment 302. In other words, the antenna system controller 102 can fulfill a plurality of channel requests from the user device equipment 302. It is to be appreciated that there can be any suitable number of user device equipment 302, such as user device equipment ₁ to user device equipment _{M}, where M is a positive integer.

The system 300 can further include a multi-channel evaluator 304 that can manage requests associated with the user device equipment 302. For example, a first user device equipment can request a first channel and a second user device equipment can request a second channel, wherein the multi-channel evaluator 304 can analyze various criteria in order to identify a directional antenna position for such multiple channel requests. For instance, the multi-channel evaluator 304 can leverage information such as, but not limited to, user device equipment priority levels (e.g., user can rank device equipment in which a higher priority or rank dictates antenna position, etc.), user defined channel priorities or rankings, a level of average signal quality for channel/transmitter requests (e.g., a position for the directional antenna that provides the highest signal quality average for each channel requested, highest signal quality average for any available channel, etc.), averaging (e.g., weighted, un-weighted, etc.), worst-case optimization, worst-case thresholding, etc.

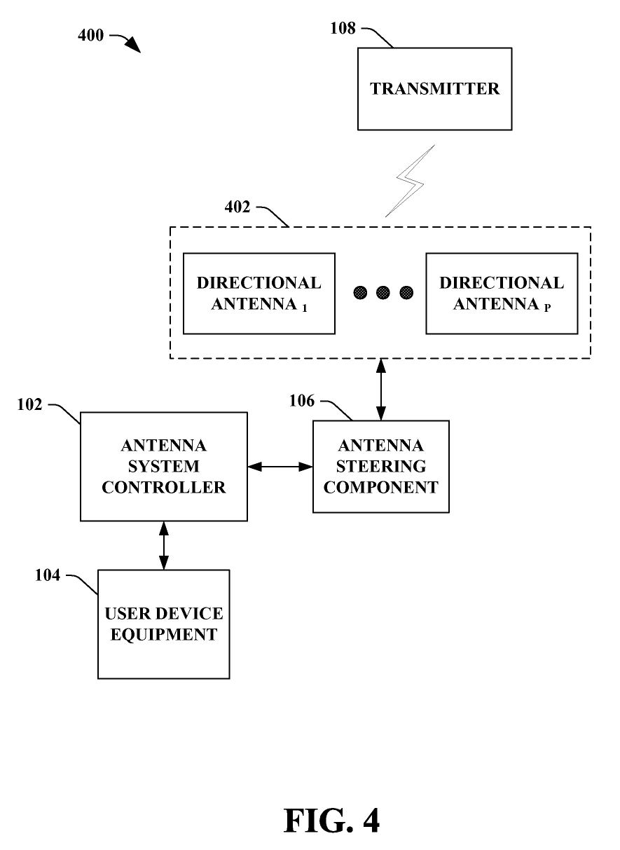

FIG. 4 illustrates a system 400 that facilitates utilizing two or more directional antennas for automatic configuration to receive terrestrial broadcast services. The system 400 can include the antenna system controller 102 that can automatically identify a position for a directional antenna for optimized over the air broadcasts that can enable user device equipment 104 to receive a transmission from the transmitter 108. Generally, the system 400 can automatically track and utilize positions for at least one directional antenna 402 in which the position can provide a level of reception to receive data or transmission from the transmitter 108. It is to be appreciated that the antenna system controller 102 can include any suitable number of directional antennas, such as directional antenna 1 to directional antenna P, where P is a positive integer.

Furthermore, the directional antenna 402 can be utilized in at least one of a scanning mode or a reception mode. A directional antenna can be utilized to continuously provide updates on antenna positions for each channel during repeated and continuous azimuths sweeps (e.g., scanning mode), whereas an additional antenna can be utilized to provide reception based on the continuous sweeps (e.g., reception mode). For example, a first directional antenna can automatically and continuously collect or gather channel/transmitter data (e.g., scanning mode) while a disparate directional antenna can leverage such gathered data in order to provide a level of reception for user device equipment 104. Moreover, it is to be appreciated that a directional antenna 402 can be in a scanning mode for a designated percentage of an azimuth sweep. In other words, a first directional antenna can be in scanning mode with a 180 azimuth sweep, a second directional antenna can be in scanning mode for the remaining 180 azimuth sweep, while a third directional antenna can be utilized in reception mode. It is to be appreciated that the above are solely for illustrative purposes only and are not to be limiting on the subject innovation.

The system 400 can automate the antenna optimization process by using information obtained from the user device(s) 104 and antenna system controller 102. The user device 104 can be the receiver from which channel selections and changes are made. The user device equipment 104 collects channel selection information from a receiver and shares it with the antenna system controller 102. The user device equipment 104 can identify a selected channel by detecting a local oscillator frequency used (e.g., by a receiver heterodyne circuitry) to convert various received channels to a common intermediate frequency. The local oscillator frequency can vary for each channel selected and may be detected from within or outside many receivers. For example, a small patch antenna can be applied to the outside of a receiver enclosure to detect the local oscillator frequency. Once detected, the local oscillator frequency can be translated to specific channel numbers using a learning process or frequency to channel lookup table loaded in the user device equipment 104. More advanced channel identification techniques can be utilized and can include direct connection to and integration with a receiver circuitry (not shown). Once known, the selected channel information can be sent from the user device equipment 104 to the antenna system controller 102 using a variety of techniques including, but not limited to, powerline data transmission, wireless (e.g., WIFI, Bluetooth, etc.), wired connection (e.g., Ethernet, cable, etc.). Thus, it is to be appreciated that the directional antenna can identify a tuned channel via detection of a local oscillator frequency from outside a receiver enclosure. Moreover, the directional antenna can forward or communicate the tuned channel information to the antenna system controller 102 via a wired or wireless mechanism.

The system 400 can include at least one directional antenna 402, the antenna steering component 106, and the antenna system controller 102 to control the antenna optimization process. The antenna system controller 102 can include receivers (not shown) to measure channels from the directional antenna and record their signal quality. The antenna system controller 102 can further include controllers to receive channel information from user device equipment 104, decide optimal antenna aiming and control the antenna steering component 106. For example, upon installation or on a routine basis after an installation, the antenna system controller 102 can survey (e.g., scan, record, etc.) signal quality for all channels, transmission technologies and antenna azimuth supported by the system 400 and user device equipment 104. Analog signal quality measurements may utilize center channel signal strength only whilst digital technologies may utilize multiple in-channel signal and flatness measurements to ascertain signal quality due to multipath. These measurements can be applied to a table and repeated for a number of azimuth settings after the antenna has been swept (e.g., in a full circle, a portion of a circle, etc.). The end result can be a stored table of channels (e.g., a row) with received quality for each sampled antenna azimuth setting (e.g., a column).

The antenna system controller 102 can receive channel information from user device equipment 104 and (e.g., using the aforementioned channel quality versus azimuth table) can identify the optimal azimuth for that channel. If different channels are sent by multiple user devices, the antenna system controller 102 can identify the azimuth that delivers the best overall quality for all channels requested. Multiple techniques may be used for such analysis, including averaging (weighted or not), worst-case optimization and thresholding. Next, the antenna system controller 102 can command and verify the antenna steering change. This process can be repeated each time a user device equipment 104 changes channels. For high mobility situations the system 400 can include multiple antennas and associated steering component 106: one for survey and the other for content reception. In this case, the survey and channel quality table updates are nearly continuous and antenna steering may be triggered by user device equipment 104 channel and survey measurement changes.

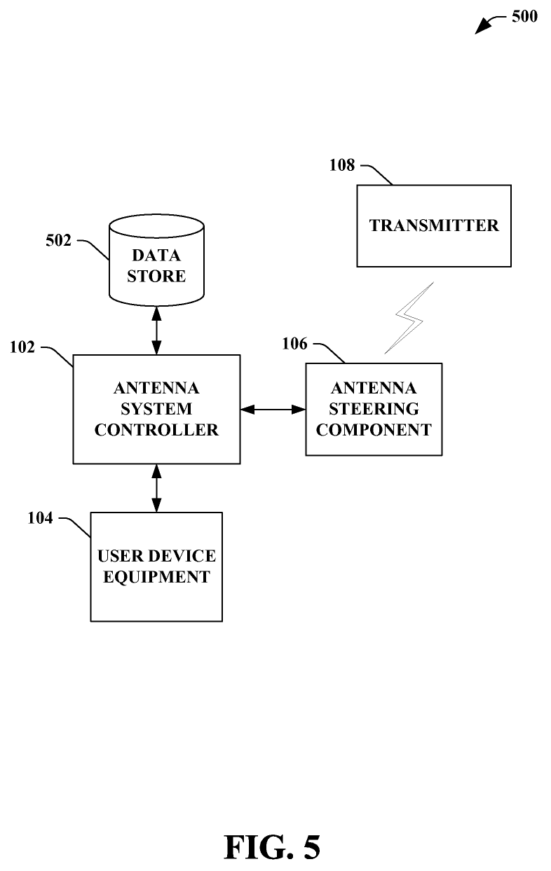

FIG. 5 illustrates a system 500 that facilitates identifying direction antenna positions that correspond to an optimal signal from a transmitter. The system 500 can further include a data store 502 that can include any suitable data utilized and/or accessed by the antenna system controller 102, the user device equipment 104, the antenna steering component 106, the transmitter 108, etc. For example, the data store 502 can include, but not limited to including, tables, graphs, azimuth data, azimuth positions for transmitters, signal quality, coordinates for directional antenna, pre-defined positions for a directional antenna and transmitters, on-the-fly defined positions for a directional antenna and transmitters, user-defined priorities for user device equipment, rankings or priority for channels, scanning or survey schedules, logging data, tracking data, error logs, etc. Moreover, although the data store 502 is depicted as a stand-alone component, it is to be appreciated that the data store 502 can be a stand-alone component, incorporated into the antenna system controller 102, the user device equipment 104, the antenna steering component 106, the transmitter 108, and/or any suitable combination thereof.

It is to be appreciated that the data store 502 can be, for example, either volatile memory or nonvolatile memory, or can include both volatile and nonvolatile memory. By way of illustration, and not limitation, nonvolatile memory can include read only memory (ROM), programmable ROM (PROM), electrically programmable ROM (EPROM), electrically erasable programmable ROM (EEPROM), or flash memory. Volatile memory can include random access memory (RAM), which acts as external cache memory. By way of illustration and not limitation, RAM is available in many forms such as static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM). The data store 502 of the subject systems and methods is intended to comprise, without being limited to, these and any other suitable types of memory. In addition, it is to be appreciated that the data store 502 can be a server, a database, a hard drive, a pen drive, an external hard drive, a portable hard drive, and the like.

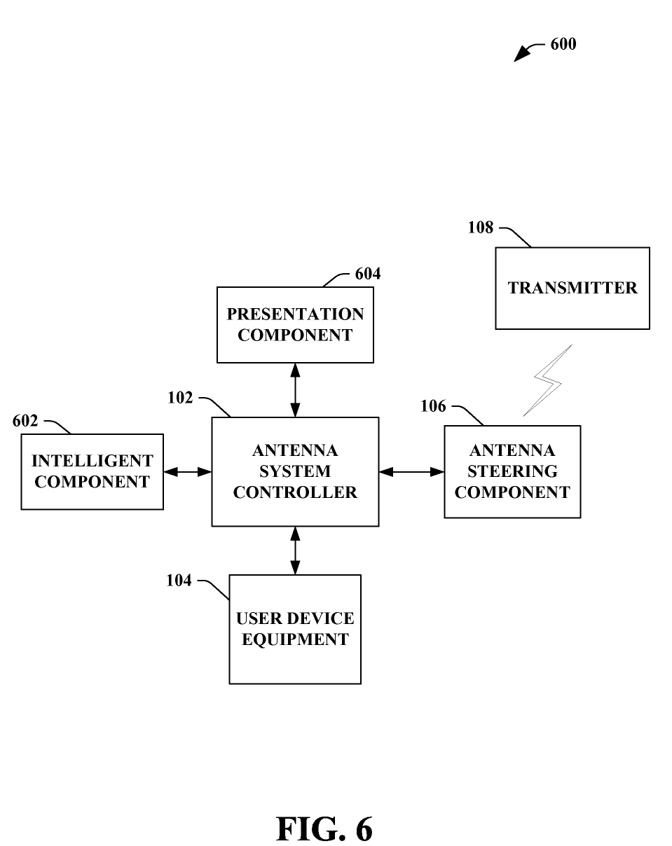

FIG. 6 illustrates a system 600 that employs intelligence to facilitate automatically inferring optimal antenna positions for efficient receipt of terrestrial broadcast services. The system 600 can include the antenna system controller 102, the user device equipment 104, the antenna steering component 106, and the transmitter 108 which can be substantially similar to respective controllers, equipment, components, and transmitters described in previous figures. The system 600 further includes an intelligent component 602. The intelligent component 602 can be utilized by the antenna system controller 102 to facilitate identifying optimal positions for directional antennas in order to receive a level of reception from transmitters. For example, the intelligent component 602 can infer user preferred channel preferences, user preferences related to user device equipment (e.g., priorities, rankings, etc.), optimal positions for transmitter reception, scanning or survey frequency, user settings, user configurations, etc.

The intelligent component 602 can employ value of information (VOI) computation in order to identify positions for the directional antenna. For instance, by utilizing VOI computation, the most ideal and/or appropriate antenna positions for transmitter reception can be determined. Moreover, it is to be understood that the intelligent component 602 can provide for reasoning about or infer states of the system, environment, and/or user from a set of observations as captured via events and/or data. Inference can be employed to identify a specific context or action, or can generate a probability distribution over states, for example. The inference can be probabilistic—that is, the computation of a probability distribution over states of interest based on a consideration of data and events. Inference can also refer to techniques employed for composing higher-level events from a set of events and/or data. Such inference results in the construction of new events or actions from a set of observed events and/or stored event data, whether or not the events are correlated in close temporal proximity, and whether the events and data come from one or several event and data sources. Various classification (explicitly and/or implicitly trained) schemes and/or systems (e.g., support vector machines, neural networks, expert systems, Bayesian belief networks, fuzzy logic, data fusion engines . . . ) can be employed in connection with performing automatic and/or inferred action in connection with the claimed subject matter.

A classifier is a function that maps an input attribute vector, x=(x1, x2, x3, x4, xn), to a confidence that the input belongs to a class, that is, f(x)=confidence(class). Such classification can employ a probabilistic and/or statistical-based analysis (e.g., factoring into the analysis utilities and costs) to prognose or infer an action that a user desires to be automatically performed. A support vector machine (SVM) is an example of a classifier that can be employed. The SVM operates by finding a hypersurface in the space of possible inputs, which hypersurface attempts to split the triggering criteria from the non-triggering events. Intuitively, this makes the classification correct for testing data that is near, but not identical to training data. Other directed and undirected model classification approaches include, e.g., naive Bayes, Bayesian networks, decision trees, neural networks, fuzzy logic models, and probabilistic classification models providing different patterns of independence can be employed. Classification as used herein also is inclusive of statistical regression that is utilized to develop models of priority.

The antenna system controller 102 can further utilize a presentation component 604 that provides various types of user interfaces to facilitate interaction between a user and any component coupled to the antenna system controller 102. The presentation component 604 can provide a user-friendly input interface to allow rich media input from a user. The presentation component 604 can be, but is not limited to being, a web portal, a downloadable stand-alone program, a web site, etc. The presentation component 604 can further be a web-based program or tool.

As depicted, the presentation component 604 is a separate entity that can be utilized with the antenna system controller 102. However, it is to be appreciated that the presentation component 604 and/or similar view components can be incorporated into the antenna system controller 102 and/or a stand-alone unit. The presentation component 604 can provide one or more graphical user interfaces (GUIs), command line interfaces, and the like. For example, a GUI can be rendered that provides a user with a region or means to load, import, read, etc., data, and can include a region to present the results of such. These regions can comprise known text and/or graphic regions comprising dialogue boxes, static controls, drop-down-menus, list boxes, pop-up menus, as edit controls, combo boxes, radio buttons, check boxes, push buttons, and graphic boxes. In addition, utilities to facilitate the presentation such as vertical and/or horizontal scroll bars for navigation and toolbar buttons to determine whether a region will be viewable can be employed. For example, the user can interact with one or more of the components coupled and/or incorporated into the antenna system controller 102.

The user can also interact with the regions to select and provide information via various devices such as a mouse, a roller ball, a touchpad, a keypad, a keyboard, a touch screen, a pen and/or voice activation, a body motion detection, for example. Typically, a mechanism such as a push button or the enter key on the keyboard can be employed subsequent entering the information in order to initiate the search. However, it is to be appreciated that the claimed subject matter is not so limited. For example, merely highlighting a check box can initiate information conveyance. In another example, a command line interface can be employed. For example, the command line interface can prompt (e.g., via a text message on a display and an audio tone) the user for information via providing a text message. The user can then provide suitable information, such as alpha-numeric input corresponding to an option provided in the interface prompt or an answer to a question posed in the prompt. It is to be appreciated that the command line interface can be employed in connection with a GUI and/or API. In addition, the command line interface can be employed in connection with hardware (e.g., video cards) and/or displays (e.g., black and white, EGA, VGA, SVGA, etc.) with limited graphic support, and/or low bandwidth communication channels.

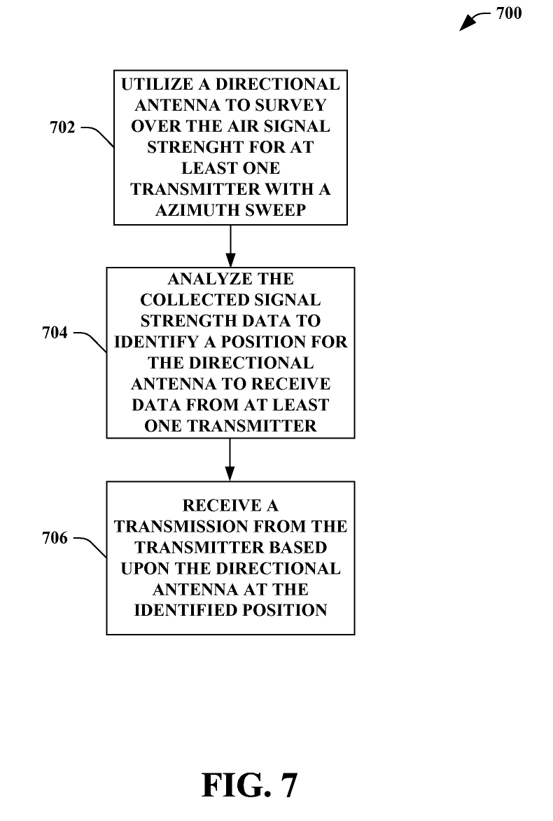

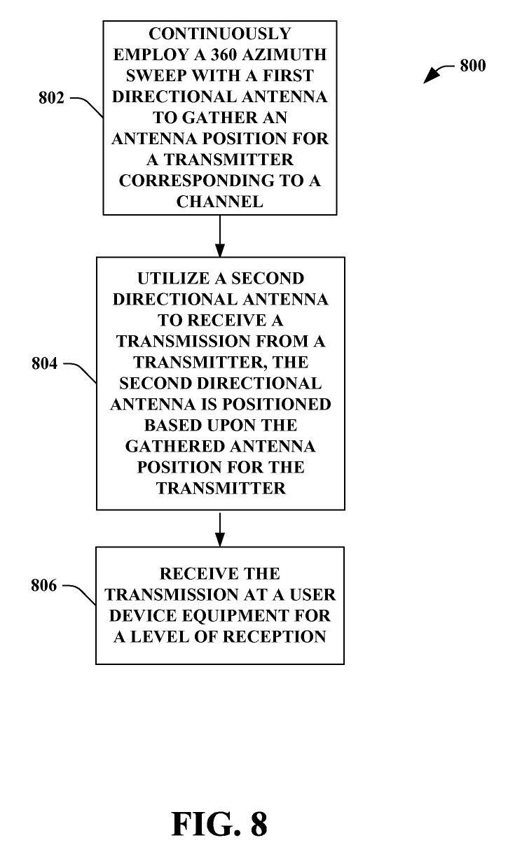

FIGS. 7-8 illustrate methodologies and/or flow diagrams in accordance with the claimed subject matter. For simplicity of explanation, the methodologies are depicted and described as a series of acts. It is to be understood and appreciated that the subject innovation is not limited by the acts illustrated and/or by the order of acts. For example acts can occur in various orders and/or concurrently, and with other acts not presented and described herein. Furthermore, not all illustrated acts may be required to implement the methodologies in accordance with the claimed subject matter. In addition, those skilled in the art will understand and appreciate that the methodologies could alternatively be represented as a series of interrelated states via a state diagram or events. Additionally, it should be further appreciated that the methodologies disclosed hereinafter and throughout this specification are capable of being stored on an article of manufacture to facilitate transporting and transferring such methodologies to computers. The term article of manufacture, as used herein, is intended to encompass a computer program accessible from any computer-readable device, carrier, or media.

FIG. 7 illustrates a method 700 that facilitates automatically optimizing a directional antenna in order to provide optimized over the air reception. At reference numeral 702, a directional antenna can be utilized to survey over the air signal strength for at least one transmitter with an azimuth sweep. For instance, the azimuth sweep can be a portion of a 360 azimuth sweep. At reference numeral 704, the collected signal strength data can be analyzed to identify a position for the directional antenna to receive data from at least one transmitter. At reference numeral 706, a transmission can be received from the transmitter based upon the directional antenna at the identified position.

FIG. 8 illustrates a method 800 for evaluating antenna aiming for multiple channel requests in which an efficient directional antenna aiming can be employed to suit each channel request. At reference numeral 802, a 360 azimuth sweep can be continuously employed with a first directional antenna to gather an antenna position for a transmitter corresponding to a channel. At reference numeral 804, a second directional antenna can be utilized to receive a transmission from a transmitter, wherein the second directional antenna is positioned based upon the gathered antenna position for the transmitter. At reference numeral 806, the transmission can be received at a user device equipment for a level of reception.

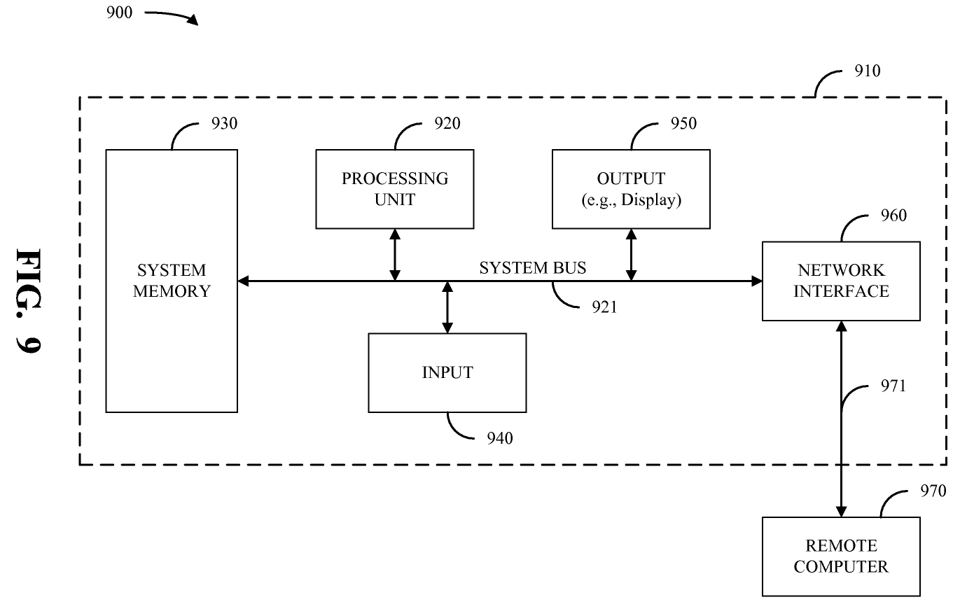

In order to provide additional context for implementing various aspects of the claimed subject matter, FIG. 9 and the following discussion is intended to provide a brief, general description of a suitable computing environment in which the various aspects of the subject innovation may be implemented. For example, an antenna system controller can collect optimal antenna position data in order to automatically adjust the antenna for reception of a transmission from a transmitter, as described in the previous figures, can be implemented in such suitable computing environment. While the claimed subject matter has been described above in the general context of computer-executable instructions of a computer program that runs on a local computer and/or remote computer, those skilled in the art will recognize that the subject innovation also may be implemented in combination with other program modules. Generally, program modules include routines, programs, components, data structures, etc., that perform particular tasks and/or implement particular abstract data types.

Moreover, those skilled in the art will appreciate that the inventive methods may be practiced with other computer system configurations, including single-processor or multi-processor computer systems, minicomputers, mainframe computers, as well as personal computers, hand-held computing devices, microprocessor-based and/or programmable consumer electronics, and the like, each of which may operatively communicate with one or more associated devices. The illustrated aspects of the claimed subject matter may also be practiced in distributed computing environments where certain tasks are performed by remote processing devices that are linked through a communications network. However, some, if not all, aspects of the subject innovation may be practiced on stand-alone computers. In a distributed computing environment, program modules may be located in local and/or remote memory storage devices.

Turning to FIG. 9, an example computing system or operating environment in which various aspects described herein can be implemented is illustrated. One of ordinary skill in the art can appreciate that handheld, portable and other computing devices and computing objects of all kinds are contemplated for use in connection with the claimed subject matter, e.g., anywhere that a network can be desirably configured. Accordingly, the below general purpose computing system described below in FIG. 9 is but one example of a computing system in which the claimed subject matter can be implemented.

Although not required, the claimed subject matter can partly be implemented via an operating system, for use by a developer of services for a device or object, and/or included within application software that operates in connection with one or more components of the claimed subject matter. Software may be described in the general context of computer executable instructions, such as program modules, being executed by one or more computers, such as client workstations, servers or other devices. Those skilled in the art will appreciate that the claimed subject matter can also be practiced with other computer system configurations and protocols.

FIG. 9 thus illustrates an example of a suitable computing system environment 900 in which the claimed subject matter can be implemented, although as made clear above, the computing system environment 900 is only one example of a suitable computing environment for a media device and is not intended to suggest any limitation as to the scope of use or functionality of the claimed subject matter. Further, the computing environment 900 is not intended to suggest any dependency or requirement relating to the claimed subject matter and any one or combination of components illustrated in the example operating environment 900.

With reference to FIG. 9, an example of a computing environment 900 for implementing various aspects described herein includes a general purpose computing device in the form of a computer 910. Components of computer 910 can include, but are not limited to, a processing unit 920, a system memory 930, and a system bus 921 that couples various system components including the system memory to the processing unit 920. The system bus 921 can be any of several types of bus structures including a memory bus or memory controller, a peripheral bus, and a local bus using any of a variety of bus architectures.

Computer 910 can include a variety of computer readable media. Computer readable media can be any available media that can be accessed by computer 910. By way of example, and not limitation, computer readable media can comprise computer storage media and communication media. Computer storage media includes volatile and nonvolatile as well as removable and non-removable media implemented in any method or technology for storage of information such as computer readable instructions, data structures, program modules or other data. Computer storage media includes, but is not limited to, RAM, ROM, EEPROM, flash memory or other memory technology, CDROM, digital versatile disks (DVD) or other optical disk storage, magnetic cassettes, magnetic tape, magnetic disk storage or other magnetic storage devices, or any other medium which can be used to store the desired information and which can be accessed by computer 910. Communication media can embody computer readable instructions, data structures, program modules or other data in a modulated data signal such as a carrier wave or other transport mechanism and can include any suitable information delivery media.

The system memory 930 can include computer storage media in the form of volatile and/or nonvolatile memory such as read only memory (ROM) and/or random access memory (RAM). A basic input/output system (BIOS), containing the basic routines that help to transfer information between elements within computer 910, such as during start-up, can be stored in memory 930. Memory 930 can also contain data and/or program modules that are immediately accessible to and/or presently being operated on by processing unit 920. By way of non-limiting example, memory 930 can also include an operating system, application programs, other program modules, and program data.

The computer 910 can also include other removable/non-removable, volatile/nonvolatile computer storage media. For example, computer 910 can include a hard disk drive that reads from or writes to non-removable, nonvolatile magnetic media, a magnetic disk drive that reads from or writes to a removable, nonvolatile magnetic disk, and/or an optical disk drive that reads from or writes to a removable, nonvolatile optical disk, such as a CD-ROM or other optical media. Other removable/non-removable, volatile/nonvolatile computer storage media that can be used in the exemplary operating environment include, but are not limited to, magnetic tape cassettes, flash memory cards, digital versatile disks, digital video tape, solid state RAM, solid state ROM and the like. A hard disk drive can be connected to the system bus 921 through a non-removable memory interface such as an interface, and a magnetic disk drive or optical disk drive can be connected to the system bus 921 by a removable memory interface, such as an interface.

A user can enter commands and information into the computer 910 through input devices such as a keyboard or a pointing device such as a mouse, trackball, touch pad, and/or other pointing device. Other input devices can include a microphone, joystick, game pad, satellite dish, scanner, or the like. These and/or other input devices can be connected to the processing unit 920 through user input 940 and associated interface(s) that are coupled to the system bus 921, but can be connected by other interface and bus structures, such as a parallel port, game port or a universal serial bus (USB). A graphics subsystem can also be connected to the system bus 921. In addition, a monitor or other type of display device can be connected to the system bus 921 via an interface, such as output interface 950, which can in turn communicate with video memory. In addition to a monitor, computers can also include other peripheral output devices, such as speakers and/or a printer, which can also be connected through output interface 950.

The computer 910 can operate in a networked or distributed environment using logical connections to one or more other remote computers, such as remote computer 970, which can in turn have media capabilities different from device 910. The remote computer 970 can be a personal computer, a server, a router, a network PC, a peer device or other common network node, and/or any other remote media consumption or transmission device, and can include any or all of the elements described above relative to the computer 910. The logical connections depicted in FIG. 9 include a network 971, such as a local area network (LAN) or a wide area network (WAN), but can also include other networks/buses. Such networking environments are commonplace in homes, offices, enterprise-wide computer networks, intranets and the Internet.

When used in a LAN networking environment, the computer 910 is connected to the LAN 971 through a network interface or adapter. When used in a WAN networking environment, the computer 910 can include a communications component, such as a modem, or other means for establishing communications over the WAN, such as the Internet. A communications component, such as a modem, which can be internal or external, can be connected to the system bus 921 via the user input interface at input 940 and/or other appropriate mechanism. In a networked environment, program modules depicted relative to the computer 910, or portions thereof, can be stored in a remote memory storage device. It should be appreciated that the network connections shown and described are non-limiting examples and that other means of establishing a communications link between the computers can be used.

What has been described above includes examples of the subject innovation. It is, of course, not possible to describe every conceivable combination of components or methodologies for purposes of describing the claimed subject matter, but one of ordinary skill in the art may recognize that many further combinations and permutations of the subject innovation are possible. Accordingly, the claimed subject matter is intended to embrace all such alterations, modifications, and variations that fall within the spirit and scope of the appended claims.

In particular and in regard to the various functions performed by the above described components, devices, circuits, systems and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the claimed subject matter. In this regard, it will also be recognized that the innovation includes a system as well as a computer-readable medium having computer-executable instructions for performing the acts and/or events of the various methods of the claimed subject matter.

There are multiple ways of implementing the present innovation, e.g., an appropriate API, tool kit, driver code, operating system, control, standalone or downloadable software object, etc. which enables applications and services to use the advertising techniques of the invention. The claimed subject matter contemplates the use from the standpoint of an API (or other software object), as well as from a software or hardware object that operates according to the advertising techniques in accordance with the invention. Thus, various implementations of the innovation described herein may have aspects that are wholly in hardware, partly in hardware and partly in software, as well as in software.

The aforementioned systems have been described with respect to interaction between several components. It can be appreciated that such systems and components can include those components or specified sub-components, some of the specified components or sub-components, and/or additional components, and according to various permutations and combinations of the foregoing. Sub-components can also be implemented as components communicatively coupled to other components rather than included within parent components (hierarchical). Additionally, it should be noted that one or more components may be combined into a single component providing aggregate functionality or divided into several separate sub-components, and any one or more middle layers, such as a management layer, may be provided to communicatively couple to such sub-components in order to provide integrated functionality. Any components described herein may also interact with one or more other components not specifically described herein but generally known by those of skill in the art.

In addition, while a particular feature of the subject innovation may have been disclosed with respect to only one of several implementations, such feature may be combined with one or more other features of the other implementations as may be desired and advantageous for any given or particular application. Furthermore, to the extent that the terms “includes,” “including,” “has,” “contains,” variants thereof, and other similar words are used in either the detailed description or the claims, these terms are intended to be inclusive in a manner similar to the term “comprising” as an open transition word without precluding any additional or other elements.

What is claimed is:

1. A system that facilitates receiving a terrestrial broadcast service from a transmitter, comprising:
an antenna steering component that automatically maneuvers a directional antenna with a 360 degree azimuth sweep in order to collect information related to a signal quality for a channel and a corresponding transmitter; and
an antenna system controller that ascertains an antenna azimuth for the directional antenna for each channel based upon the collected information, the antenna azimuth corresponds to a position of the directional antenna that receives a level of reception from the transmitter.

2. The system of claim 1, further comprising a user device equipment that receives the level of reception from the transmitter related to an over the air broadcast.

3. The system of claim 2, the over the air broadcast relates to at least one of a high definition (HD) television signal, a satellite signal, an analog signal, a digital signal, a wireless signal, a network signal, or a server communication.

4. The system of claim 3, the antenna system controller receives a channel request from the user device equipment, the channel request corresponds to a channel that correlates to a specific transmitter.

5. The system of claim 4, the antenna system controller instructs the directional antenna to a position to receive a transmission for the specific transmitter in accordance with the 360 degree azimuth sweep.

6. The system of claim 1, the level of reception is defined by at least one of a pre-defined level of signal quality, a measurement of signal quality, a percentage of a signal quality, a percentage of a maximum signal quality, a maximum detected signal quality from the transmitter, or a defined level of signal quality.

7. The system of claim 1, further comprising two or more user device equipment that provide two or more channel requests.

8. The system of claim 7, further comprising a multi-channel evaluator that ascertains a position for the directional antenna based upon an analysis of the collected information, the collected information relates to two or more transmitters.

9. The system of claim 8, the multi-channel evaluator identifies a position for the directional antenna to receive reception for the two or more transmitters related to the channel requests based upon the analysis.

10. The system of claim 9, the analysis relates to at least one of a user device equipment priority level, a user defined channel ranking, a level of an average signal quality for the channel requests, a weighted averaging of the channel requests, an un-weighted averaging of the channel requests, a worst-case optimization, or a worst-case thresholding.

11. The system of claim 1, the directional antenna is in a scanning mode that continuously gathers information with the 360 degree azimuth sweep, the gathered information relates to a plurality of positions and corresponding signal strength for a plurality of transmitters.

12. The system of claim 11, further comprising a second directional antenna that is in a reception mode to handle a channel request.

13. The system of claim 12, the second directional antenna maneuvers to a position for a received channel request based at least in part upon the directional antenna in the scanning mode that continuously gathers information.

14. The system of claim 1, the antenna system controller implements a periodic 360 azimuth sweep to collect information related to a signal quality for a channel and a corresponding transmitter.

15. The system of claim 1, the directional antenna: identifies a tuned channel via detection of a local oscillator frequency from outside a receiver enclosure and forwards the aforementioned tuned channel information to the antenna system controller via at least one of a wired or wireless mechanism.

16. A computer-implemented method that facilitates optimizing a directional antenna for reception of a transmission over the air, comprising:
utilizing a directional antenna to survey over the air signal strength for at least one transmitter with an azimuth sweep;
analyzing the collected signal strength data to identify a position for the directional antenna to receive data from at least one transmitter; and
receiving a transmission from the transmitter based upon the directional antenna at the identified position.

17. The method of claim 16, further comprising:
continuously employing the azimuth sweep with a first directional antenna to gather an antenna position for a transmitter corresponding to a channel;
utilizing a second directional antenna to receive a transmission from a transmitter, the second directional antenna is positioned based upon the gathered antenna position for the transmitter;
receiving the transmission at a user device equipment for a level of reception;
identifying tuned channel information via a detection of local oscillator frequency from outside a receiver enclosure; and
forwarding the tuned channel information to be utilized for receiving the transmission via at least one of a wired mechanism or a wireless mechansim.

18. The method of claim 17, the user device equipment receives the level of reception from the transmitter related to an over the air broadcast, the over the air broadcast relates to at least one of a high definition (HD) television signal, a satellite signal, an analog signal, a digital signal, a wireless signal, a network signal, or a server communication.

19. The method of claim 17, the level of reception is defined by at least one of a pre-defined level of signal quality, a measurement of signal quality, a percentage of a signal quality, a percentage of a maximum signal quality, a maximum detected signal quality from the transmitter, or a defined level of signal quality.

20. A computer-implemented system that facilitates receiving a terrestrial broadcast service from a transmitter, comprising:
means for automatically maneuvering a directional antenna with a 360 degree azimuth sweep in order to collect information related to a signal quality for a channel and a corresponding transmitter; and
means for ascertaining an antenna azimuth for the directional antenna for each channel based upon the collected information, the antenna azimuth corresponds to a position of the directional antenna that receives a level of reception from the transmitter;
means for receiving a channel request corresponding to the transmitter;
means for positioning the directional antenna for the channel request based upon the collected information;
means for identifying tuned channel information via a detection of local oscillator frequency from outside a receiver enclosure; and
means for forwarding the tuned channel information to be utilized for collecting information related to the signal quality via at least one of a wired mechanism or a wireless mechanism.
